(19) United States
(12) Patent Application Publication
(10) Pub. No.: US 2022/0049373 A1
(43) Pub. Date: Feb. 17, 2022

(54) SIC SINGLE CRYSTAL(S) DOPED FROM GAS PHASE

(71) Applicant: II-VI Delaware, Inc, Wilmington, DE (US)

(72) Inventors: Ilya Zwieback, Twp. Of Washington, NJ (US); Varatharajan Rengarajan, Flanders, NJ (US)

(21) Appl. No.: 17/444,863

(22) Filed: Aug. 11, 2021

Related U.S. Application Data
(60) Provisional application No. 63/064,041, filed on Aug. 11, 2020.

(51) Int. Cl. C30B 23/06; C30B 29/36; C23C 14/06

(52) U.S. Cl. CPC C30B 23/066; C23C 14/0635; C30B 29/36

(57) ABSTRACT

An apparatus for sublimation growth of a doped SiC single crystal includes a growth crucible, an envelope, a heater, and a passage for introducing into the envelope from a source outside the envelope a doping gas mixture. The gas mixture includes a gaseous dopant precursor that, in response to entering a space between the growth crucible and the envelope, undergoes chemical transformation and releases into the space between the growth crucible and the envelope dopant-bearing gaseous products of transformation which penetrate the wall of the crucible, move into the crucible, and absorb on a growth interface of a growing SiC crystal thereby causing doping of the growing crystal. A sublimation growth method is also described.

### CROSS REFERENCE TO RELATED APPLICATION

This application claims priority to U.S. Provisional Patent Application No. 63/064,041, filed Aug. 11, 2020. The entire disclosure of U.S. Provisional Patent Application No. 63/064,041 is incorporated herein by reference.

### BACKGROUND

There is a need in the art for an improved method and apparatus for forming one or more silicon carbide (SiC) single crystals. There is also a need in the art for an improved method and apparatus for growing one or more doped SiC single crystals using a gaseous source of dopant. The present disclosure overcomes the deficiencies of prior art methods and apparatuses to a substantial extent.

### SUMMARY

The present disclosure relates to a method of growing a doped silicon carbide (SiC) single crystal by sublimation. The method includes providing SiC source material and a SiC single crystal seed in spaced relation within a growth crucible; holding the growth crucible in an envelope, and providing passages for a gas between an exterior surface of the growth crucible and an interior surface of the envelope; heating the SiC source material to form sublimated material, establishing a temperature gradient between the SiC source material and the SiC single crystal seed, and causing the sublimated material to be transported to and precipitate on the SiC single crystal seed; and using the passages to introduce into the envelope, from a source outside the envelope, a doping gas mixture including a gaseous dopant precursor, and heating the gaseous dopant precursor, within the passages, to a temperature between 2000° C. and 2400° C., such that the gaseous dopant precursor undergoes a chemical transformation and releases into the space between the growth crucible and the envelope dopant-bearing gaseous products which penetrate the crucible wall, move into the crucible, and absorb on a growth interface of a growing SiC crystal.

The present disclosure also relates to an apparatus for sublimation growth of a doped SiC single crystal. The apparatus includes a growth crucible, having a wall and an exterior surface, for holding a silicon carbide (SiC) source material and a SiC single crystal seed in spaced relation; an envelope, having an interior surface, for holding the growth crucible in the envelope in spaced relation such that space for a gas exists between the exterior surface of the crucible and the interior surface of the envelope; a heater for heating the growth crucible to sublime the SiC source material, and for forming a temperature gradient between the SiC source material and the SiC single crystal seed that causes the sublimated SiC source material to be transported to and precipitate on the SiC single crystal seed and thereby grow a SiC crystal on the SiC single crystal seed; and a passage for introducing into the envelope from a source outside the envelope a doping gas mixture that includes a gaseous dopant precursor that, in response to entering the space between the growth crucible and envelope, undergoes chemical transformation and releases into the space between the growth crucible and envelope dopant-bearing gaseous products of transformation which penetrate the wall of the crucible, move into the crucible and absorb on a growth interface of a growing SiC crystal thereby causing doping of the growing SiC crystal.

### BRIEF DESCRIPTION OF THE DRAWINGS

FIG. 1 is a schematic view of a known crystal growth system;

FIG. 2 is a schematic view of a gas-assisted crystal growth system;

FIG. 3 is a schematic view of a modified gas-assisted crystal growth system; and

FIG. 4 is a schematic view of an example of an apparatus for growing one or more silicon-carbide single crystals in accordance with the present disclosure.

Throughout the drawings, like elements are designated by like reference numerals and other characters. The drawings show non-limiting examples for purposes of illustration and explanation of the present disclosure, and are not drawn to scale.

### DETAILED DESCRIPTION

Single crystals of silicon carbide (SiC) of 4H and 6H polytypes are used in a variety of electronic and optoelectronic applications. They can be used, for example, as lattice-matched substrates in epitaxial SiC-based power switching devices, epitaxial GaN-based ultra-high-frequency transistors, light emitting diodes (LEDs), laser diodes, and in many other devices.

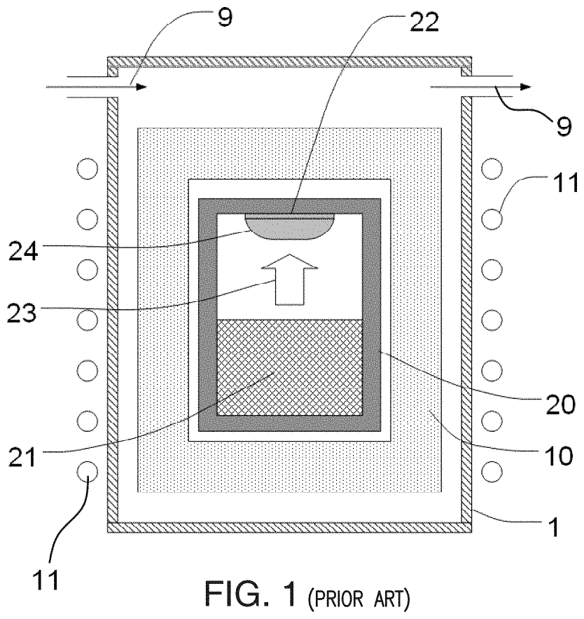

Large-size, commercial SiC single crystals are grown by the sublimation technique of physical vapor transport (PVT). A PVT crystal growth system is shown schematically in FIG. 1. The growth system includes a double-wall, water-cooled furnace chamber 1 made from fused silica. A PVT growth cell is disposed inside the furnace chamber 1 and includes a crystal growth crucible 20 made of graphite and charged with polycrystalline SiC source material 21 and a SiC single crystal seed 22. The SiC source material 21 is disposed at the bottom of the growth crucible 20, while the SiC seed 22 is disposed at the top and attached to the crucible lid.

The system shown in FIG. 1 has a heater, including an inductive coil 11, placed outside the chamber 1. When energized, the coil 11 radio-frequency (RF)-couples to the crucible 20. The crucible 20 is surrounded by thermal insulation 10 made from light-weight fibrous graphite. Other parts of the PVT crystal growth apparatus of FIG. 1, including gas and vacuum lines, valves, pumps, electronic controls, etc., are not shown in FIG. 1. Resistive heating, different RF heating arrangements, and furnace chambers made of other than fused silica materials, such as stainless steel, are also known in the art of SiC sublimation growth.

In preparation for PVT growth, the chamber 1, containing the crucible 20 with the SiC source material 21 and the seed 22, is evacuated, filled with a process gas (most commonly, pure argon) to a desired pressure, commonly between several and 20 Torr, and a flow of a process gas is established across the chamber 1, as symbolized by arrows 9. Then, the crucible 20 is heated to the growth temperature, generally between 2000 and 2400° C. The vertical position of the coil 11 is such that a vertical temperature gradient is created in the crucible 20, with the temperature of the SiC source material 21 being higher than the temperature of the seed 22.

At high temperatures, the SiC source material 21 sublimes (or, is sublimated), releasing a spectrum of volatile molecular species, such as Si, Si₂C and SiC₂, into the interior of the crucible 20. Driven by the vertical temperature gradient, these species migrate to the SiC seed 22 and condense on the seed 22, causing growth of the SiC single crystal 24 on the SiC seed 22. Vapor transport in the FIG. 1 configuration is symbolized by arrow 23.

Dopants may be deliberately introduced into the SiC crystal lattice to alter electronic and optical parameters of the crystal, and to meet the requirements of a specific device. SiC crystals and epilayers of p-type can be grown using doping with elements of Group III of the periodic table, such as boron, aluminum and gallium. SiC crystals and epilayers of n-type can be grown using doping with Group V elements, such as nitrogen and phosphorus. Semi-insulating SiC crystals can be grown using doping with transition metals, such as vanadium. Other dopants, such as beryllium, germanium, and scandium, may also be explored.

In-situ doping during PVT growth of SiC may be performed by introducing a solid dopant into the growth crucible. The solid dopant can be in elemental form or in the form of a stable chemical compound, such as carbide. For instance, vanadium and aluminum doping has been carried out using elemental vanadium, vanadium carbide (VC), elemental aluminum and aluminum carbide (Al₄C₃). Solid dopants have been admixed directly into the SiC source material or contained in an inert capsule buried in the SiC source material.

At high temperatures of PVT growth, a solid dopant disposed in the growth crucible goes through chemical transformations, including thermal dissociation and chemical reactions with the SiC source material. The transformations lead to spatially nonuniform distribution of the dopant in the grown SiC crystal, with the dopant concentration spiking in the first-to-grow crystal portions followed by a rapidly declining doping level. In-situ doping during PVT growth using solid dopants offers little to no control over the dopant concentration in the crystal.

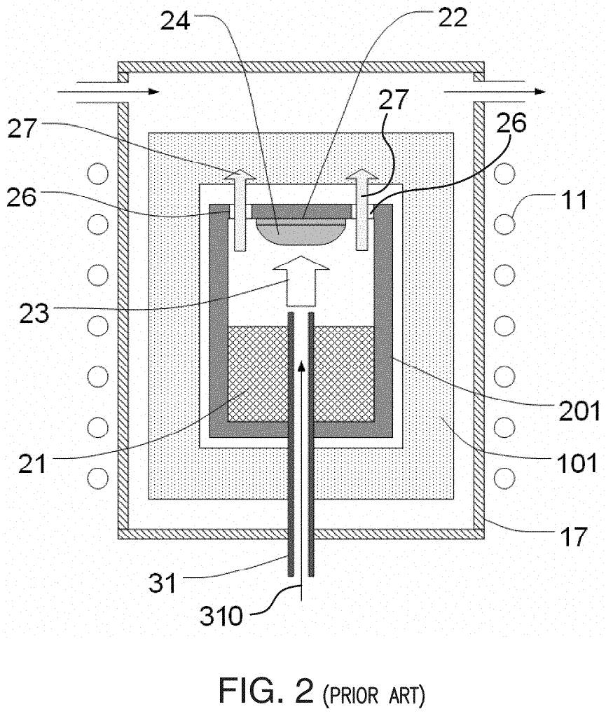

In order to solve this problem, gas-assisted PVT growth incorporating in-situ doping from the gas phase may be performed. Such growth processes include advanced PVT (APVT), high temperature chemical vapor deposition (HTCVD), halide CVD (HCVD), continuous feed PVT (CF PVT), and modified PVT (M-PVT). FIG. 2 shows a generalized, conceptual diagram of APVT, HTCVD, HCVD, and CF PVT gas-assisted PVT methods and systems. In such processes, the growth crucible 201 may have multiple passages for gas entry and exit. In operation, a gas mixture 310 containing a gaseous dopant precursor mixed with a carrier gas and, in some cases, with silicon and carbon precursors, is supplied into the growth crucible 20 via a conduit 31. Gaseous byproducts 27 leave the crucible 20 via open exit passages (openings) 26 through the crucible wall.

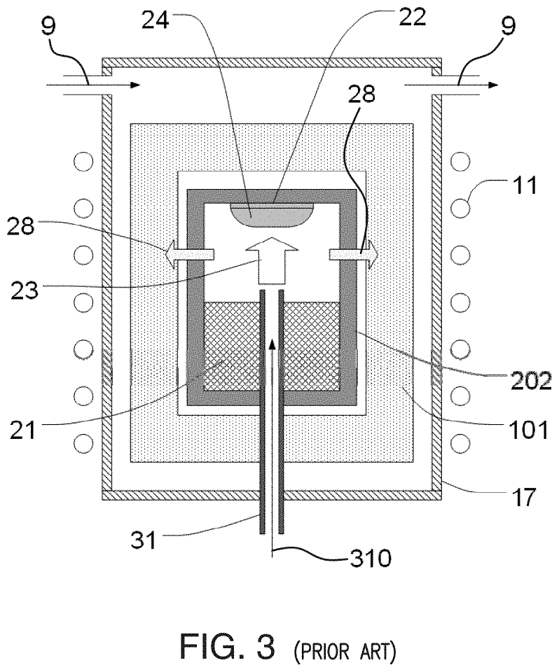

FIG. 3 illustrates a gas-assisted M-PVT process. In this method, the crucible 202 has an inlet passage 31 for gas entry, but no passages or openings in the wall of the crucible 202 for gas exit. In operation, gaseous byproducts escape the crucible 202 by filtering across (that is, by being transported radially outwardly through) the porous, gas-permeable crucible wall, as symbolized by arrows 28.

U.S. Pat. No. 9,322,110 and Japanese Patent Document No. 5,623,071 refer to modifications of an M-PVT growth technique developed for doping a SiC crystal with vanadium and aluminum, respectively. Vanadium tetrachloride (VCl₄) is mentioned as a gaseous vanadium precursor in U.S. Pat. No. 9,322,110, while trimethyl aluminum (TMA, Al(CH₃)₃) is mentioned as a gaseous aluminum precursor in Japanese Patent Document No. 5,623,071.

Gas-assisted PVT growth systems may have drawbacks. The gas mixture entering the crucible via the gas conduit 31 may interfere with the vapor transport originating from the SiC source material 21. As a result, the growth interface of the growing SiC crystal 24 may have an unwanted or disadvantageous shape, such as concave or wavy. In the configuration illustrated in FIG. 2, the presence of passages or openings 26 in the crucible 201 may lead to severe silicon and carbon losses caused by the removal of vapor from the crucible 201 by gas flow through the openings 26. In the configuration illustrated in FIG. 3, gas pressure in the growth crucible 202 may be unpredictable and difficult to control, which may lead to poor control over the crystal growth rate.

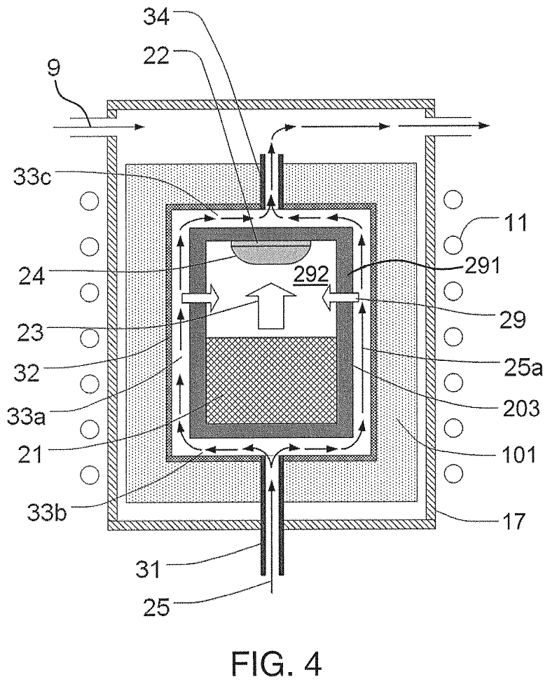

FIG. 4 shows an example of a PVT crystal growth process and apparatus for yielding one or more SiC single crystals uniformly doped with one or more impurities. According to the present disclosure, in-situ doping from the gas phase may be combined with PVT growth carried out in a sealed graphite crucible having no passages or openings.

Synthetic graphite (hereinafter referred to as “graphite”) has high permeability to gases and vapors. Graphite contains a network of open and closed pores, cracks, and grain boundaries. Mass transport of a gas in graphite includes the following major mechanisms: (i) gas phase movement via open pores; (ii) diffusion along the pore surfaces associated with physical and chemical absorption and desorption; (iii) diffusion along the grain boundaries; and (iv) dopant accumulation in the closed or dead-end pores combined with diffusion across the pore wall.

As used herein, the term “opening” refers to a passage which provides a much larger flow path than any flow path within the open and closed pores, cracks, and grain boundaries of graphite. As the term is used herein, the open and closed pores, cracks, and grain boundaries of graphite do not include or provide an “opening” through or within the graphite.

Mass transport of a gas in graphite may be described in terms of “permeation,” “infiltration,” and “diffusion,” and these terms may be used interchangeably. The rate of mass transport of a gas in graphite is characterized by the graphite material's effective permeability coefficient (κ). The value of κ depends on the nature of the gas phase and the graphite type. At temperatures of about 2000° C., the value of κ for ordinary iso-molded graphite is on the order of 10⁻¹ to 10⁻⁴ cm²/s. For graphite treated to reduce its porosity, the value of κ can be many orders of magnitude less than 10⁻¹ to 10⁻⁴ cm²/s.

According to the present disclosure, a method and apparatus are provided which differ from known gas-assisted PVT processes in the way the dopant is delivered into the growth crucible. In the known process, dopant or its precursor is delivered into the growth crucible by a carrier gas flowing from the crucible exterior into the crucible interior through one or more openings in the crucible. According to the present disclosure, in contrast, the growth crucible has no opening and the gaseous dopant precursor is delivered to a space exterior to the crucible and adjacent to the crucible wall. While in this space outside of the crucible, chemical transformations of the precursor take place, leading to the appearance of stable, dopant-bearing gaseous molecules. This gaseous dopant permeates across (that is, is transported radially inwardly through) the porous crucible wall 291, in the direction of arrows 29, from a position (33a) outside the crucible wall 291 to a position within the interior 292 of the crucible 203, adsorbs on the growth interface, and causes doping of the growing SiC crystal 24.

The crystal growth apparatus illustrated in FIG. 4 has a furnace chamber 17 and a heater, such as a radio frequency (RF) coil 11 wound around the chamber 17. A graphite growth crucible 203 is disposed inside the chamber 1. The crucible 203 is surrounded by thermal insulation 101. The crucible 203 may be, if desired, in the form of a closed cylinder with a circular, disc-shaped wall on the bottom and a circular, disc-shaped lid on the top. The thermal insulation 101 may be formed from light-weight fibrous graphite. The illustrated crucible 203 is charged with polycrystalline SiC source material 21, and a SiC seed 22 is located within the crucible 203, spaced apart from the source material 21, for PVT growth. The lid of the crucible 203 may be used, if desired, to load the source material 21 and the seed 22 inside the crucible 203.

The PVT apparatus shown in FIG. 4 has a cylindrical envelope 32, with the growth crucible 203 disposed inside the envelope 32. The envelope 32 and the crucible 203 are preferably coaxial and radially spaced from each other (that is, there is an annular free space including a gap 33a, 33b, 33c between the inside surface of the envelope 32 and the outside surface of the crucible 203). The free space includes the illustrated annular gap 33a, a bottom disc-shaped gap 33b, and a top disc-shaped gap 33c. The envelope 32 is connected to a gas inlet conduit 31 and a gas outlet conduit 34. During PVT growth, the inlet conduit 31, the gaps 33a, 33b, 33c, and the outlet conduit 34 form one or more pathways for the movement of the doping gas mixture supplied via the inlet conduit 31. The flow of the doping gas mixture is symbolized by arrows 25, 25a.

According to one aspect of the present disclosure, the growth crucible 203, the envelope 32, and the gas conduits 31, 34 are all made from graphite. Desirably, the material of the growth crucible 203 is iso-molded, fine-grain graphite, such as Mersen grade 2020 or Toyo Tanso grade IG-11 or another suitable material. The density of the graphite material may be, desirably, between 1.68 and 1.75 g/cm³. The present disclosure should not be limited, however, to the example illustrated in FIG. 4.

The material of the cylindrical envelope 32 and the gas conduits 31, 34 may also be graphite. However, the graphite of the envelope 32 and the conduits 31, 34 is desirably treated to reduce its permeability. An example of such a treated material is Mersen graphite grade CARBOGRAF 400 produced by impregnation of graphite with vitreous carbon. The resulting material has orders of magnitude lower permeability compared to untreated graphite. The graphite material of the envelope 32 may be less permeable than the graphite material of the crucible 203.

The growth crucible 203 may have various, suitable dimensions. The thickness of the wall of the illustrated crucible 203 is preferably between 8 and 16 mm. Inner diameters of the gas conduits 31, 34 are, desirably, between 10 and 25 mm and their wall thickness may be, desirably, between 5 and 20 mm. Again, however, the present disclosure should not be limited to the example illustrated in FIG. 4.

The interior dimensions of the cylindrical envelope 32 are greater than the outer dimensions of the crucible 203 such that the envelope 32 accommodates the crucible 203 and provides space for the gaps 33a, 33b, 33c. The widths of the gaps 33a, 33b, 33c are, desirably, between 6 and 10 mm. The wall thickness of the cylindrical envelope 32 is, desirably, between 4 and 8 mm. A desired coaxial position of the crucible 203 inside the envelope 32 can be achieved using one or more suitable devices, such as graphite spacers, supports, etc. (not illustrated in the drawings).

The cylindrical envelope 32 and the conduits 31, 34 may be connected in a suitable manner, for example, by threading (not illustrated). At the bottom of the chamber 17, the inlet conduit 31 may be connected to a metal gas line (not illustrated). A gas-tight connection between the graphite conduit 31 and the metal gas line may be achieved by any suitable technique, for example, by threading using carbonaceous sealants or gaskets (not illustrated).

If desired, the growth chamber 17 may contain thermal insulation 101, and the cylindrical envelope 32 may be surrounded by the thermal insulation 101. Within the furnace chamber 17, the envelope 32 may be connected to the inlet gas conduit 31. The crucible 203 charged with the SiC source material 21 and the SiC seed 22 is disposed inside the cylindrical envelope 32.

In operation, the chamber 17 may be evacuated and filled with the process gas 9 which may be pure argon, to a pressure, desirably, between several and 20 Torr. A flow of the process gas 9 is established across the chamber 17 at a flow rate, desirably, between 100 and 500 sccm.

Then, the RF coil 11 may be energized to heat the growth crucible 203 and the cylindrical envelope 32 to the PVT growth temperature which is, desirably, between 2000 and 2400° C. The axial position of the coil 11 is adjusted to create a vertical temperature gradient in the growth crucible 203 with the temperature at the crucible bottom being higher than at the crucible top. The vertical temperature gradient, from the crucible bottom to the crucible top, may be, for example, between 20 and 50° C. The temperatures of the crucible bottom and top may be monitored, if desired, using an optical pyrometer.

Upon reaching the temperatures of SiC sublimation growth, the SiC source material 21 vaporizes and fills the interior of the crucible 203 with Si- and C-bearing vapors including Si, Si₂C, and SiC₂ molecules. Driven by the vertical temperature gradient, these vapors migrate toward the SiC seed 22, as illustrated by arrow 23. Upon approaching the SiC seed 22, the vapors condense on the seed 22, causing growth of the SiC single crystal 24 on the SiC seed 22.

Simultaneously, a flow of doping gas mixture is allowed into the envelope 32 via the conduit 31, as shown by arrow 25. The gas mixture includes a gaseous dopant precursor and a carrier gas. The carrier gas may be a pure inert gas, such as argon, or an inert gas containing, for example, a hydrogen additive or a halogen additive or both. As the doping gas mixture travels through the conduit 31 and reaches the annular and lower-disc-shaped gaps 33a, 33b, the temperature of the doping gas mixture increases to initiate chemical transformations.

The chemical transformations depend on the nature of the dopant, its precursor, and the presence of chemically active components that may be added to the inert gas. When the precursors are volatile and not thermally stable, such transformations may be limited to pyrolysis. For less volatile dopants or precursors, more complex transformations may be needed to form stable gaseous molecules, if desired, by adding chemically active components to the carrier gas. These chemically active gaseous components may contain hydrogen-bearing molecules or halogen-bearing molecules or molecules where both hydrogen and halogen are present.

According to one aspect of the present disclosure, the flow rate of the doping gas mixture at the entrance of the conduit 31 is, desirably, between 10 and 100 sccm.

The result of the above-mentioned transformations is the appearance in the annular gap 33a of gaseous products of transformations which may include elemental gaseous dopant or dopant-bearing gaseous molecules. The gaseous products of transformations diffuse across (that is, diffuse radially inwardly through) the porous wall 291 of the graphite crucible 203 into the interior 292 of the crucible 203. Once inside the crucible 203, the gaseous dopant migrates toward the growing SiC single crystal 24, adsorbs on the growth interface of the growing crystal 24, and causes doping of the SiC single crystal 24.

The process illustrated in FIG. 4 does not require any passage or opening through the wall 291 of the growth crucible 203 to serve as a gas inlet or outlet. The crucible 203 preferably does not contain any such passage or opening. Therefore, losses of silicon and carbon constituents from the crucible 203 occur only by diffusion of the gaseous Si- and C-bearing molecules across (that is, radially outwardly through) the porous crucible wall 291. Such losses may be negligible compared to the amount of material in the SiC single crystal 24.

Practical examples of the present disclosure described herein include PVT growth of SiC single crystals in-situ doped with phosphorus, aluminum, and vanadium. These three examples should not be construed as limiting the scope of the present disclosure. Various suitable dopants, other than or in addition to, the ones mentioned herein may be selected and used without forming refractory carbide compounds stable at temperatures of SiC sublimation growth.

In the practical examples described herein, the PVT growth apparatus and parameters of the PVT growth process were as follows: The growth crucible 203 had the following dimensions: 175 mm ID×200 mm OD×250 mm tall. The crucible 203 was machined from halogen-purified graphite grade 2020 of Mersen. The cylindrical envelope 32 had the following dimensions: 216 mm inner diameter (ID)×230 mm outer diameter (OD)×270 mm tall. The envelope 32 was manufactured from graphite/carbon grade CARBOGRAF 400 of Mersen (graphite impregnated with vitreous carbon).

The inlet gas conduit 31 had the following dimensions: 20 mm ID×36 mm OD. The outlet gas conduit 34 had the following dimensions: 20 mm ID×30 mm OD. Both conduits were manufactured from graphite/carbon grade CARBOGRAF 400 of Mersen. The gas conduits 31, 34 were attached to the cylindrical envelope 32 by threading. In each example, the SiC seed 22 was a 4H-SiC wafer with a diameter of 150 mm. The SiC source material (the sublimation source) 21 was high-purity SiC grain.

The growth process temperature at the crucible bottom and top were monitored using an optical pyrometer. In each growth run, the axial position of the RF coil 11 was adjusted to reach the following temperatures: about 2260° C. at the crucible bottom and about 2220° C. at the crucible top. The process gas was UHP 99.9995% argon. During growth, the chamber pressure was maintained at 10 Torr with an argon flow rate of 500 sccm.

Example 1: Growth of SiC Single Crystal Doped with Phosphorus. A 4H—SiC growth run combined with phosphorus doping in accordance with the present disclosure has been carried out. The doping gas mixture consisted of a phosphorus precursor, phosphine (PH₃), and pure argon as a carrier gas (50 ppm of phosphine in argon). The flow rate of the doping mixture supplied to the inlet conduit 31 (FIG. 4) was 10 sccm.

As phosphine carried by argon travels through the conduit 31 and the gaps 33a, 33b, its temperature increases to the point where pyrolysis of the compound starts. Phosphine (PH₃) starts decomposing at 550° C. yielding first a tetramer molecule P₄, then a dimer P₂, and then, at higher temperatures, a monomer P. The elemental phosphorus vapor penetrates the porous wall of the graphite crucible 203. Once inside the crucible 203, phosphorus adsorbs on the SiC growth interface causing n-type doping of the SiC single crystal 24.

The grown 4H—SiC crystal boule was sliced into 150 mm diameter wafers. The electrical resistivity of the wafers was measured and mapped using a non-contact, eddy current tool LEI3200. First-to-grow and last-to-grow wafer coupons were sent for secondary ion mass spectroscopy (SIMS) analysis on phosphorus. The results showed a uniform n-type electrical resistivity of the wafers of about 0.1 Ohm-cm±15%. The phosphorus concentration as determined by SIMS in the wafer coupons was between 8×10¹⁶ and 1×10¹⁷ cm⁻³.

Example 2: Growth of SiC Single Crystal Doped with Aluminum. A 4H—SiC growth run combined with aluminum doping in accordance with the present disclosure has been carried out. The doping gas mixture consisted of an aluminum precursor, trimethyl aluminum (TMA, Al(CH₃)₃), and argon which served as a carrier gas. TMA is liquid at room temperature; therefore, it was handled and injected into the growth system using a bubbler. High-purity TMA was pre-packaged in a stainless steel, ready-for-use bubbler. Design and operation of bubbler systems containing volatile precursors and heated gas lines are known in the art. The bubbler temperature was maintained at 25° C. The flow rate of the argon carrier gas supplied to the bubbler inlet was 20 sccm.

As TMA carried by argon travels through the conduit 31 and the gaps 33a, 33b, its temperature increases to initiate its pyrolysis. TMA pyrolysis starts at temperatures between 500 and 700° C. with the main product being gaseous dimethyl aluminum (DMA). At higher temperatures, the main product of pyrolysis is gaseous monomethyl aluminum (MMA). At even higher temperatures, MMA decomposes yielding elemental aluminum vapor. In the presence of solid carbon, the appearance of solid aluminum carbide (Al₄C₃) can be expected. However, at high temperatures of SiC sublimation growth, Al₄C₃ is unstable and decomposes into solid carbon plus Al+C liquid plus monoatomic aluminum vapor. The elemental aluminum vapor penetrates and passes through the wall 291 of the crucible 203, and adsorbs on the SiC growth interface causing p-type doping of the SiC single crystal 24.

The grown SiC crystal boule was sliced into 150 mm diameter wafers. The electrical resistivity of the wafers was measured and mapped using a non-contact, eddy current tool LEI3200. First-to-grow and last-to-grow wafer coupons were sent for SIMS analysis on aluminum. The results showed a uniform p-type electrical resistivity of the wafers of about 0.8 Ohm-cm±20%. The aluminum concentration as determined by SIMS was between 8×10¹⁶ and 3×10¹⁷ cm⁻³.

Example 3: Growth of a SiC Single Crystal Doped with Vanadium. A 4H—SiC growth run combined with vanadium doping in accordance with the present disclosure has been carried out. The doping gas mixture consisted of a vanadium precursor (vanadium tetrachloride, VCl₄) and a two-component carrier gas consisting of 90% argon plus 10% hydrogen (H₂). The VCl₄ precursor is liquid at room temperature. Therefore, it was handled and injected using a bubbler. High-purity VCl₄ was purchased from Millipore Sigma pre-packaged in a stainless steel, ready-for-use bubbler.

The 90% Ar+10% H₂ carrier gas was supplied to the bubbler inlet at a rate of 20 sccm. The bubbler was maintained at 40° C. In the process of bubbling, vapor of the vanadium precursor (VCl₄) mixes with carrier gas and is then injected into growth crucible 203 via gas conduit 31.

The chemistry of the VCl₄ precursor transformations involves reactions between gaseous VCl₄ and H₂ leading to the appearance of gaseous HCl and volatile vanadium-bearing molecules of VCl₃ and VCl₂. Thermodynamic modeling shows that, at high temperatures of SiC sublimation growth, VCl₂ species dominates over VCl₃. This vanadium-bearing vapor penetrates across (that is, through) the wall of the crucible 203 into the crucible interior and causes doping of the SiC single crystal 24 with vanadium.

The grown SiC crystal boule was sliced into 150 mm diameter wafers. The electrical resistivity of the wafers was measured and mapped using a non-contact, capacitance-based tool (COREMA-WT). First-to-grow and last-to-grow wafer coupons were sent for SIMS analysis on vanadium. The sliced wafers were semi-insulating with resistivity of 1×10¹⁰ Ohm-cm or higher. The vanadium concentration as determined by SIMS was between 4×10¹⁶ and 7×10¹⁶ cm⁻³.

What have been described above are examples. This disclosure is intended to embrace alterations, modifications, and variations to the subject matter described herein that fall within the scope of this application, including the appended claims. As used herein, the term “includes” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements. The order in which steps are recited in the claims is not, by itself, limiting.

What is claimed as new and desired to be protected by Letters Patent of the United States is:

1. A method of growing a doped silicon carbide (SiC) single crystal by sublimation, comprising:
providing SiC source material and a SiC single crystal seed in spaced relation within a growth crucible;
holding the growth crucible in an envelope, and providing passages for a gas between an exterior surface of the growth crucible and an interior surface of the envelope;
heating the SiC source material to form sublimated material, establishing a temperature gradient between the SiC source material and the SiC single crystal seed, and causing the sublimated material to be transported to and precipitate on the SiC single crystal seed; and
using the passages to introduce into the envelope, from a source outside the envelope, a doping gas mixture including a gaseous dopant precursor, and heating the gaseous dopant precursor, within the passages, to a temperature between 2000° C. and 2400° C., such that the gaseous dopant precursor undergoes a chemical transformation and releases into the space between the growth crucible and the envelope dopant-bearing gaseous products which penetrate the crucible wall, move into the crucible, and absorb on a growth interface of a growing SiC crystal.

2. The method of claim 1, further comprising holding the envelope in a furnace chamber while the growth crucible is disposed in the envelope.

3. The method of claim 1, wherein the doped SiC single crystal is of 4H or 6H polytype.

4. The method of claim 1, wherein the doping gas mixture includes a carrier gas.

5. The method of claim 4, wherein the carrier gas is an inert gas.

6. The method of claim 5, wherein the inert gas includes gaseous additives of hydrogen and/or halogen.

7. The method of claim 4, wherein the gaseous dopant precursor is chosen from the group of volatile hydride compounds, volatile halogenated compounds, and volatile metallo-organic compounds.

8. The method of claim 7, wherein the gaseous dopant precursor is phosphine (PH₃).

9. The method of claim 7, wherein the gaseous dopant precursor is trimethyl aluminum (Al(CH₃)₃).

10. The method of claim 7, wherein the gaseous dopant precursor is vanadium tetrachloride (VCl₄).

11. The method of claim 1, wherein the growth crucible has no open passages for gas entry or escape.

12. The method of claim 1, wherein the growth crucible and the envelope are formed from graphite.

13. The method of claim 11, wherein the envelope is formed from graphite treated to have reduced permeability.

14. An apparatus for sublimation growth of a doped SiC single crystal, comprising:
a growth crucible, having a wall and an exterior surface, for holding a silicon carbide (SiC) source material and a SiC single crystal seed in spaced relation;
an envelope, having an interior surface, for holding the growth crucible in the envelope in spaced relation such that space for a gas exists between the exterior surface of the crucible and the interior surface of the envelope;
a heater for heating the growth crucible to sublime the SiC source material, and for forming a temperature gradient between the SiC source material and the SiC single crystal seed that causes the sublimated SiC source material to be transported to and precipitate on the SiC single crystal seed and thereby grow a SiC crystal on the SiC single crystal seed; and
a passage for introducing into the envelope from a source outside the envelope a doping gas mixture that includes a gaseous dopant precursor that, in response to entering the space between the growth crucible and envelope, undergoes chemical transformation and releases into the space between the growth crucible and envelope dopant-bearing gaseous products of transformation which penetrate the wall of the crucible, move into the crucible and absorb on a growth interface of a growing SiC crystal thereby causing doping of the growing SiC crystal.

15. The apparatus of claim 14, further comprising a furnace chamber for holding the envelope while the growth crucible is disposed in the envelope.

16. The apparatus of claim 14, wherein the gas mixture includes a carrier gas.

17. The apparatus of claim 16, wherein the carrier gas is an inert gas.

18. The apparatus of claim 17, wherein the inert gas includes gaseous additives of hydrogen and/or halogen.

19. The apparatus of claim 16, wherein the gaseous dopant precursor is chosen from the group of volatile hydride compounds, volatile halogenated compounds, and volatile metallo-organic compounds.

20. The apparatus of claim 19, wherein the gaseous dopant precursor is phosphine (PH₃).

21. The apparatus of claim 19, wherein the gaseous dopant precursor is trimethyl aluminum (Al(CH₃)₃).

22. The apparatus of claim 19, wherein the gaseous dopant precursor is vanadium tetrachloride (VCl₄).

23. The apparatus of claim 14, wherein the growth crucible and the envelope are formed from graphite.

24. The apparatus of claim 23, wherein the envelope is formed from graphite treated to have reduced permeability.
